(19) United States
(12) Patent Application Publication
(10) Pub. No.: US 2026/0082681 A1
(43) Pub. Date: Mar. 19, 2026

(54) Asymmetric Sic Trench Mosfet Cell with an Embedded Super Barrier Rectifier

(71) Applicant: Nami MOS CO., LTD., New Taipei City (TW)

(72) Inventors: Fu-Yuan HSIEH, New Taipei City (TW); Lin XU, Shanghai (CN)

(73) Assignees: Nami MOS CO., LTD., New Taipei City (TW); MOSEL VITELIC INC., Hsinchu (TW)

(21) Appl. No.: 18/889,791

(22) Filed: Sep. 19, 2024

(51) Int. Cl. H01L 29/78; H01L 29/06; H01L 29/16; H01L 29/40

(52) U.S. Cl. CPC H10D 84/146; H10D 30/668; H10D 62/111; H10D 62/127; H10D 62/8325; H10D 64/117

(57) ABSTRACT

An integrated circuit comprising a SiC MOSFET and a SiC super barrier rectifier (SBR) disposed in one unit cell having an asymmetric trench gate electrode structure formed in a stripe gate trench is disclosed. A first channel region of the SiC MOSFET is formed along a first trench sidewall of the gate trench while a second channel region of the SiC SBR is formed along a first portion of a second trench sidewall opposite to the first trench sidewall of the gate trench. A source metal connects with a source region, body regions, and the gate electrode of the SiC SBR directly, and connects with a P-shield (PS) region below the gate trench through a grounded P (GP) region along a second portion of the second gate trench sidewall.

### FIELD OF THE INVENTION

This invention relates generally to a unit cell structure of a semiconductor device, and more particularly, to integrate a novel SiC Metal Oxide Semiconductor Field Effect Transistor (MOSFET) and a SiC Super Barrier Rectifier (SBR) into a same gate trench structure with a P-shield (PS) region below the gate trench. The SiC integrated circuit cell having a first channel region of the SiC MOSFET formed along a first trench sidewall of a gate trench and a second channel region of the SiC SBR which is a MOS channel diode formed along a first portion of a second trench sidewall opposite to the first trench sidewall of the gate trench to inactivate parasitic body diodes for turn-off switching loss reduction. Moreover, a grounded P (GP) region is formed along a second portion of the second trench sidewall of the gate trench to ground the PS region to a source metal through a source contact for the gate oxide electric field reduction. The SiC SBR and the GP region in this invention share the same second trench sidewall without scarifying the whole channel region along the second trench sidewall for the GP region as a prior part addressed below.

### BACKGROUND OF THE INVENTION

Because of the physical properties of SiC, SiC-MOSFETs can achieve a higher breakdown voltage, a lower on-resistance and a higher switching speed than Si-MOSFETs. However, SiC-MOSFETs have a higher electric-field strength at the gate oxide than Si-MOSFETs because of a poor interface state between SiC and the gate oxide requiring a higher gate-source voltage Vgs to fully turn on the device channel. e.g., for Si device, Vgs=10V can fully turn on the Si device channel but for SiC requires at least Vgs=18V. The higher Vgs causes a higher electric filed strength at the gate oxide resulting in a reliability issue.

FIG. 1A˜1C show three embodiments of a prior art (U.S. Pat. No. 9,923,066 B2) having a shield zone 103-2 wrapping around the right-hand sidewall of a gate trench 14 and partial trench bottom region 14-1 for the gate oxide protection. However, the embodiments scarify 50% channel region for the installation of the shield zone 103-2 along the right-hand sidewall of the gate trench 14 resulting in a high specific on-resistance. On the other hand, the prior art does not have the embedded SBR to suppress the turn on of the parasitic body diode, which will cause bipolar deterioration.

Therefore, there is still a need in the art of the SiC semiconductor device design and fabrication to provide a novel cell structure, device configuration and manufacturing process that would resolve this difficulty and design limitations, making SiC trench devices have a lower electric-field strength at the gate oxide, achieve a lower on-resistance and a lower turn-off switching loss.

### SUMMARY OF THE INVENTION

The present invention discloses an integrated circuit comprising a SiC MOSFET and a SiC SBR disposed in each unit cell having an asymmetric gate trench structure comprising: a first gate electrode of the SiC MOSFET padded on a first gate oxide along a first gate trench sidewall, and a second gate electrode of the SiC SBR padded on a second gate oxide along a first portion of a second gate trench sidewall, wherein the second gate oxide has a gate oxide thickness thinner than that of the first gate oxide; the SiC SBR has a channel length shorter than that of the SiC MOSFET; a P-Shield (PS) region disposed below a bottom of each gate trench; at least one grounded P region (GP) region surrounding a second portion of a second gate trench sidewall and a portion of a bottom of each gate trench, connecting with the PS region to a source metal.

According to one aspect, the invention features an integrated circuit further comprising the stripe gate trench having a first type gate trench and a second type gate trench; the first type gate trench is above the second type gate trench and has a trench width wider than that of the second type gate trench; the first gate electrode disposed in the first gate trench surrounded with a first insulating film on a bottom of the first type gate trench, and with a first gate oxide on the first gate trench sidewall of the first type gate trench; the first insulating film having a thickness greater than that of the first gate oxide; the second gate electrode disposed in the first gate trench surrounded with a second insulating film on a bottom of the first type gate trench, and with a second gate oxide on the second gate trench sidewall of the first type gate trench; the second insulating film having a thickness greater than that of the second gate oxide; and the PS region of the second conductivity type surrounding the second type gate trench is filled up with the first insulating film; and the first insulating film has a thickness greater than that of the second insulating film.

According to one aspect, the GP region is formed at each end of the second gate electrode and a SBR region is formed between the two GP regions. According to another aspect, the GP and the SBR regions are alternately formed along the second gate trench sidewall of the gate trench.

According to another aspect, in some preferred embodiments, the substrate has the first conductivity type, further comprises a second P-shield (Pr) region of a second conductivity type for the gate oxide electric-field reduction adjoining a lower surface of the body region and being apart from the gate trench. In some other preferred embodiments, the device further comprises a super junction (SJ) structure comprising a P column (PC) region of a second conductivity type disposed above the substrate.

According to another aspect, in some preferred embodiments, further comprising an N-shield (Ns) region of the first conductivity type below the PS region having a doping concentration higher than that of the epitaxial layer for the gate oxide protection.

According to another aspect, the invention also features a SiC power device having a shielded gate electrode disposed below the first and the second gate electrodes and isolated from the two gate electrodes by an inter-polysilicon oxide (IPO) film, and the thickness of the IPO film below the first gate electrode is thicker than that below the second gate electrode.

According to another aspect, in some preferred embodiments, the substrate has the first conductivity type and the epitaxial layer has multiple stepped epitaxial (MSE) layers with different doping concentrations decreasing stepwise in a direction from a bottom of the shielded gate electrode to a top surface of the epitaxial layer, wherein each of the MSE layers has a uniform doping concentration as grown.

According to another aspect, in some preferred embodiments, the substrate has the first conductivity type and the epitaxial layer comprises a single epitaxial layer having a uniform doping concentration with a resistivity R, the SiC power device further comprises a buffer layer of the first conductivity type with a resistivity Rb sandwiched between the substrate and the epitaxial layer, wherein R<Rb. In some other preferred embodiments, the substrate has the second conductivity type and the epitaxial layer comprises a single epitaxial layer having a uniform doping concentration with a resistivity R, the SiC power device further comprises a buffer layer of the first conductivity type with a resistivity Rb sandwiched between the substrate and the epitaxial layer, wherein R>Rb.

According to another aspect, in some preferred embodiments, the substrate has the second conductivity type, further comprises a buffer layer of the first conductivity type formed sandwiched between the substrate and the epitaxial layer, and a plurality of heavily doped regions of the first conductivity type in the substrate to form a plurality of alternating P+ and N+ regions in the substrate.

According to another aspect, in some preferred embodiments, further comprising a source-body contact (SBC) trench penetrating through the source region and the body region and extending into the epitaxial layer, a bottom P-shield (BPS) region of the second conductivity type surrounding a bottom of the SBC trench and being spaced apart from the gate trench, a sidewall P (SP) region of the second conductivity type formed along sidewalls of the SBC trench connecting the BPS region to the body contact region, at least two sidewall P-shield (SPS) regions of the second conductivity type facing each other horizontally adjoining the SP region, and a Junction Field Effect Transistor (JFET) region of the first conductivity type formed between the two SPS regions.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A˜1C are cross-sectional views of semiconductor devices of a prior art (U.S. Pat. No. 9,923,066 B2).

FIG. 2A is a top view of a preferred embodiment for a trench semiconductor power device with stripe cells layout according to the present invention.

FIG. 2B is a top view of another preferred embodiment for a trench semiconductor power device with stripe cells layout according to the present invention.

FIG. 3A is a cross-sectional view showing a preferred A1-A1′ cross section of FIG. 2A according to the present invention.

FIG. 3B is a cross-sectional view showing a preferred B1-B1′ cross section of FIG. 2A according to the present invention.

FIG. 3C is a cross-sectional view showing a preferred C1-C1′ cross section of FIG. 2A according to the present invention.

FIG. 3D is a cross-sectional view showing a preferred D1-D1′ cross section of FIG. 2A according to the present invention.

FIG. 3E is a cross-sectional view showing another preferred A1-A1′ cross section of FIG. 2A according to the present invention.

FIG. 3F is a cross-sectional view showing another preferred A1-A1′ cross section of FIG. 2A according to the present invention.

FIG. 4A is a cross-sectional view showing another preferred A1-A1′ cross section of FIG. 2A according to the present invention.

FIG. 4B is a cross-sectional view showing another preferred B1-B1′ cross section of FIG. 2A according to the present invention.

FIG. 5A is a cross-sectional view showing another preferred A1-A1′ cross section of FIG. 2A according to the present invention, wherein the doping concentration variations of the N type epitaxial layer as grown are depicted along the vertical direction.

FIG. 5B is a cross-sectional view showing another preferred A1-A1′ cross section of FIG. 2A according to the present invention, wherein the doping concentration variations of the N type epitaxial layer as grown are depicted along the vertical direction.

FIG. 5C is a cross-sectional view showing another preferred A1-A1′ cross section of FIG. 2A according to the present invention, wherein the doping concentration variations of the N type epitaxial layer as grown are depicted along the vertical direction.

FIG. 5D is a cross-sectional view showing another preferred A1-A1′ cross section of FIG. 2A according to the present invention, wherein the doping concentration variations of the N type epitaxial layer as grown are depicted along the vertical direction.

FIG. 6A is a cross-sectional view showing another preferred A1-A1′ cross section of FIG. 2A according to the present invention.

FIG. 6B is a cross-sectional view showing another preferred B1-B1′ cross section of FIG. 2A according to the present invention.

FIG. 7A is a cross-sectional view showing another preferred A1-A1′ cross section of FIG. 2A according to the present invention.

FIG. 7B is a cross-sectional view showing another preferred B1-B1′ cross section of FIG. 2A according to the present invention.

FIG. 8A is a cross-sectional view showing another preferred A1-A1′ cross section of FIG. 2A according to the present invention.

FIG. 8B is a cross-sectional view showing another preferred B1-B1′ cross section of FIG. 2A according to the present invention.

FIG. 9A is a cross-sectional view showing another preferred A1-A1′ cross section of FIG. 2A according to the present invention.

FIG. 9B is a cross-sectional view showing another preferred B1-B1′ cross section of FIG. 2A according to the present invention.

FIG. 10A is a cross-sectional view showing another preferred A1-A1′ cross section of FIG. 2A according to the present invention.

FIG. 10B is a cross-sectional view showing another preferred A1-A1′ cross section of FIG. 2A according to the present invention.

FIG. 11 is a top view of another preferred embodiment for a trench semiconductor power device with stripe cells layout according to the present invention.

FIG. 12A is a cross-sectional view showing a preferred A2-A2′ cross section of FIG. 11 according to the present invention.

FIG. 12B is a cross-sectional view showing a preferred B2-B2′ cross section of FIG. 11 according to the present invention.

FIG. 12C is a cross-sectional view showing another preferred A2-A2′ cross section of FIG. 11 according to the present invention.

FIG. 13A is a cross-sectional view showing another preferred A2-A2′ cross section of FIG. 11 according to the present invention.

FIG. 13B is a cross-sectional view showing another preferred B2-B2′ cross section of FIG. 11 according to the present invention.

FIG. 14A is a cross-sectional view showing another preferred A2-A2′ cross section of FIG. 11 according to the present invention.

FIG. 14B is a cross-sectional view showing another preferred B2-B2′ cross section of FIG. 11 according to the present invention.

FIG. 15A is a cross-sectional view showing another preferred A2-A2′ cross section of FIG. 11 according to the present invention.

FIG. 15B is a cross-sectional view showing another preferred B2-B2′ cross section of FIG. 11 according to the present invention.

FIG. 16A is a cross-sectional view showing another preferred A2-A2′ cross section of FIG. 11 according to the present invention.

FIG. 16B is a cross-sectional view showing another preferred A2-A2′ cross section of FIG. 11 according to the present invention.

FIG. 17 is a cross-sectional view showing another preferred A1-A1′ cross section of FIG. 2A according to the present invention.

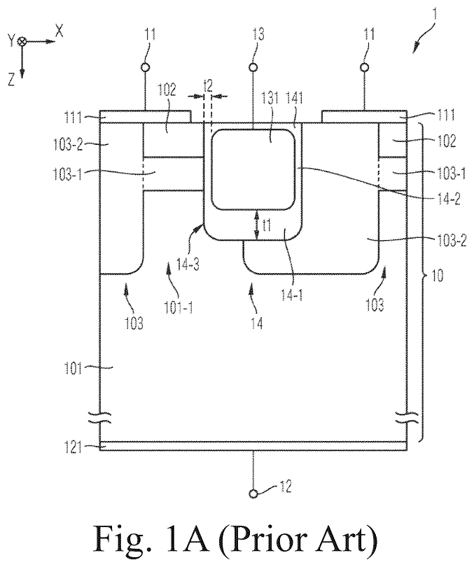

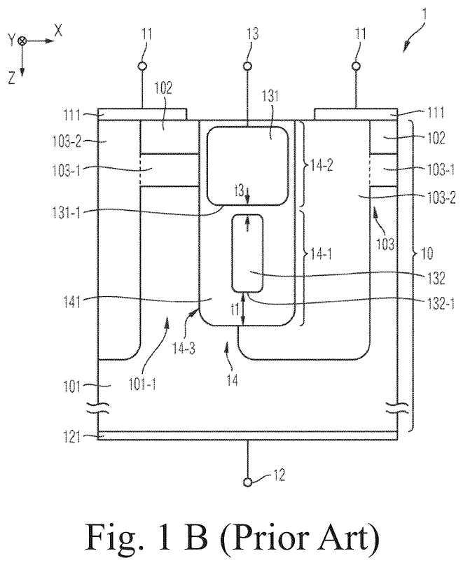

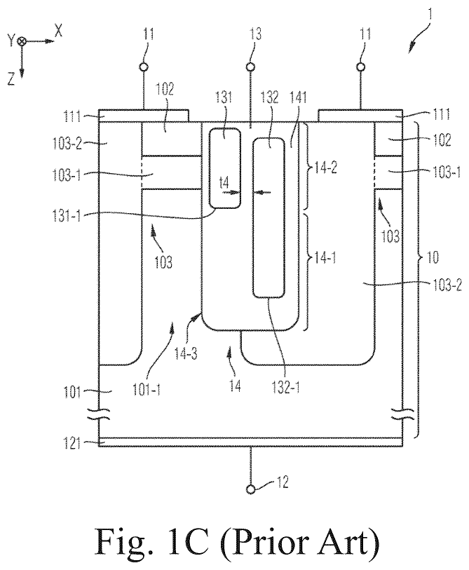

### ILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

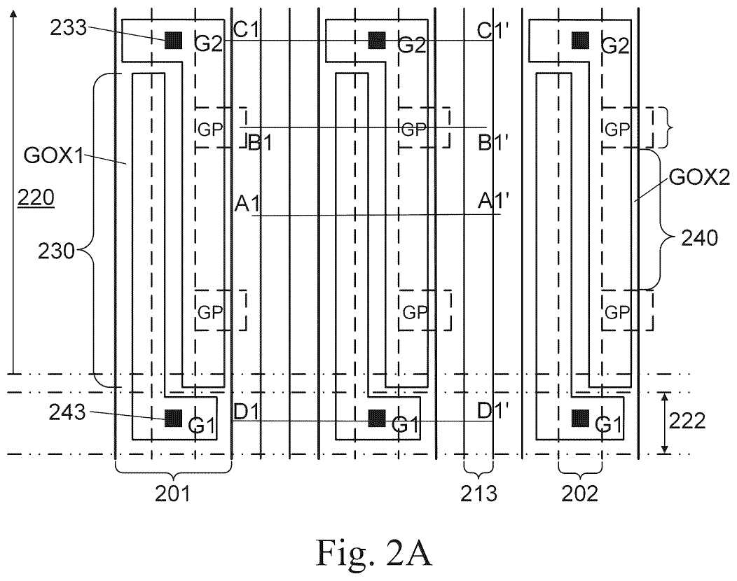

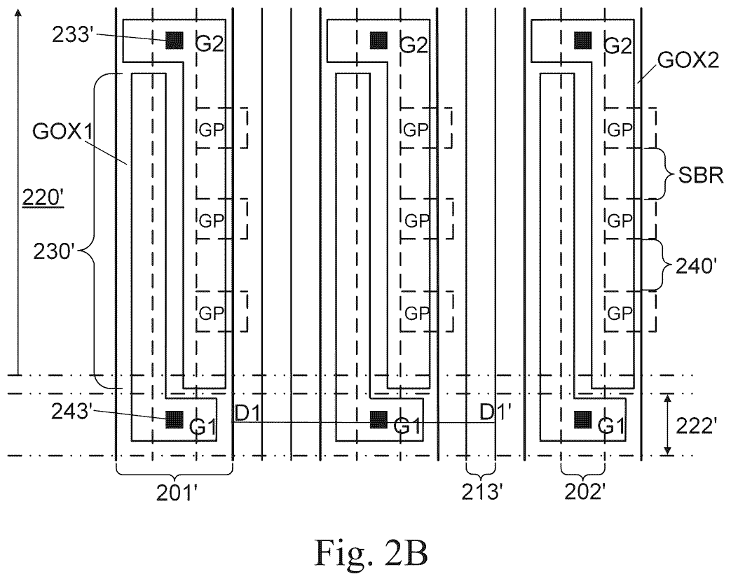

Please refer to FIG. 2A for a top view of a SiC power device having an asymmetric gate trench structure with stripe cells layout. A stripe gate trench 201 surrounds a P-shield (PS) region 202 in each unit cell, and trenched source contacts 213 are disposed between the adjacent gate trenches 201. Moreover, the PS region 202 is grounded to a source metal 220 through the grounded P (GP, as illustrated) regions and the trenched source contact 213. According to this invention, a MOSFET channel region 230 is formed along a first sidewall of the gate trench 201 with a gate oxide GOX1 and a SBR channel region 240 is formed along a second sidewall of the gate trench 201 between the two GP regions with a gate oxide GOX2, wherein GOX1 has a thickness thicker than that of GOX2. Two gate electrodes are formed in the gate trench 201, wherein the first gate electrode is shorted to a gate metal runner 222 through a gate contact (G1, as illustrated) 243 of the SiC MOSFET and the second gate electrode is shorted to a source metal 220 through a gate contact (G2, as illustrated) 233 of the SiC SBR.

Please refer to FIG. 2B for another top view of a SiC power device having an asymmetric gate trench structure with stripe cells layout. The SiC power device has a similar structure to FIG. 2A, except that in the present invention, the GP regions and the SBR regions 240′ are alternately formed along the second trench sidewall of the gate trench 201′.

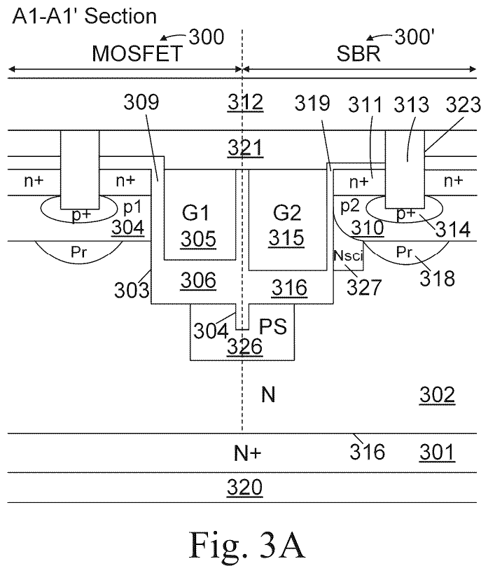

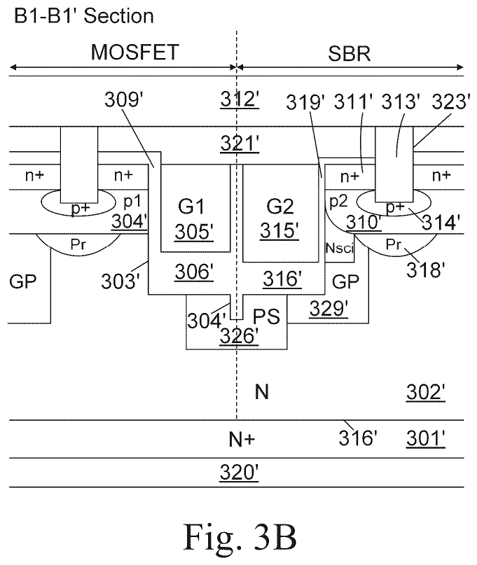

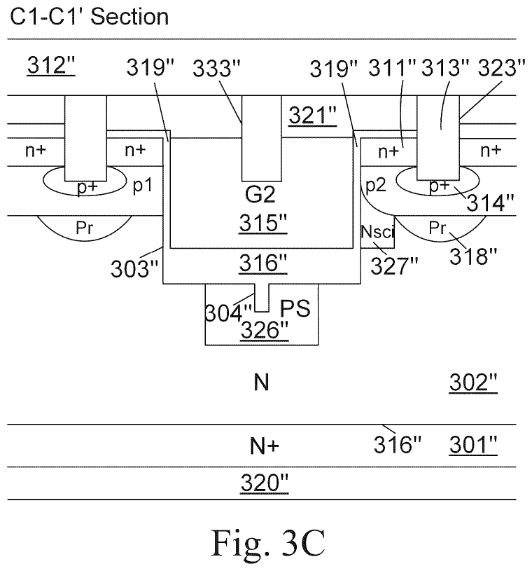

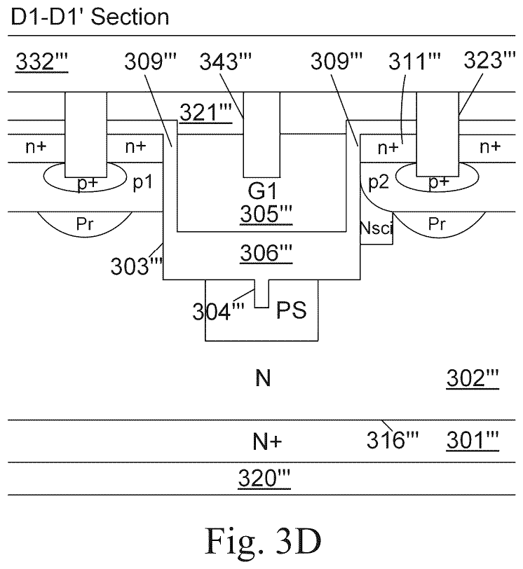

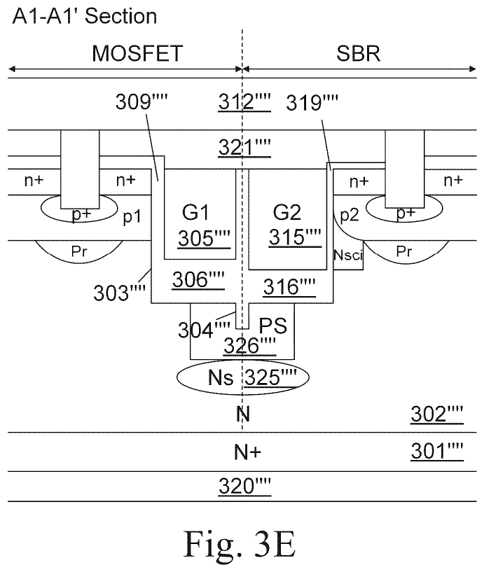

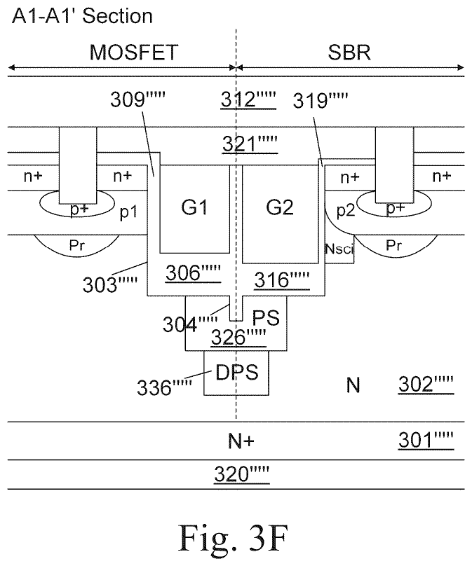

Please refer to FIG. 3A for a preferred embodiment of A1-A1′ cross-sectional view of FIG. 2A wherein an N-channel SiC MOSFET 300 and a SiC SBR 300′ are integrated on a single chip which is formed on an N+ substrate 301 with a less doped N type epitaxial layer 302 extending thereon, wherein the N+ substrate is coated with a back metal 320 on rear side as a drain metal. Inside the N type epitaxial layer 302, a plurality of gate trenches having a first type gate trenches 303 and a second type gate trenches 304 are formed vertically downward from a top surface of the N type epitaxial layer 302 and not reaching the common interface 316 between the N type epitaxial layer 302 and the N+ substrate 301, wherein the first type gate trenches 303 are above the second type gate trenches 304 and a width of the first type gate trenches 303 is greater than that of the second type gate trenches 304. Inside each of the first type gate trenches 303, a first gate electrode (G1, as illustrated) 305 of the SiC MOSFET 300 and a second gate electrode (G2, as illustrated) 315 of the SiC SBR 300′ are formed side by side in the upper portion. The first gate electrode 305 is isolated from the adjacent epitaxial layer by a first gate oxide (GOX1) 309 of the SiC MOSFET 300 on the first gate trench sidewall and a first insulating film 306 on a bottom of the first type gate trench 303 with a thickness greater than that of the first gate oxide 309. The second gate electrode 315 is isolated from the adjacent epitaxial layer with a second gate oxide (GOX2) 319 of the SiC SBR 300′ on the second gate trench sidewall and a second insulating film 316 on a bottom of the first type gate trench 303 with a thickness greater than that of the second gate oxide 319, wherein the second insulating film 316 has a thickness thinner than that of the first insulating film 306 and the thickness of the second gate oxide 319 is thinner than that of the first gate oxide 309. In the MOSFET 300, a p1 body region 304 having a n+ source region 311 thereon is extending in an upper portion of the N type epitaxial layer 302 and surrounding the first gate electrodes 305 padded by the first gate oxide film 309, wherein a first channel region is formed between the p1 body region 304 and the source region 311 along the first gate trench sidewall; while in the SBR 300′, a short channel implant (Nsci, as illustrated) region 327 is formed along upper sidewalls of the first gate trench 303 surrounding the second gate electrode 315, a p2 body region 310 having the n+ source region 311 thereon is extending in an upper portion of the N type epitaxial layer 302 and surrounding the second gate electrode 315 padded by the second gate oxide film 319, a second channel region is formed between the p2 body region 310 and the source region 311 along the second gate trench sidewall having a shorter channel length than the first channel region of the MOSFET 300. An interlayer dielectric film 321 is stacked on the epitaxial layer 302, and a source metal 312 is formed onto the interlayer dielectric film 321. The p1 body region 304, the p2 body region 310 and the n+ source regions 311 are shorted to a source metal 312 through a plurality of trenched contacts 323 filled with contact metal plugs and metal barriers 313 and surrounded by p+ heavily doped regions 314 around bottoms underneath the n+ source regions 311. Besides, the second type gate trenches 304 are filled up with the first insulating film 306. According to this invention, the P-shield (PS, as illustrated) regions 326, which surround the second type gate trenches 304, are introduced into the N type epitaxial layer 302 by an angle ion-implantation of aluminum or boron, or by combination of a zero-degree ion implantation through a bottom of the second type gate trenches 304, or by a boron doped silicon glass (BSG) layer deposition procedure. A width of the PS region 326 is designed narrower than that of the first type gate trench 303 as the second type gate trench 304 has a narrower width than the first type gate trench 303. Moreover, another p type gate oxide electric field reducing (Pr, as illustrated) regions 318 are formed as the second P-shield regions, adjoining lower surfaces of the p body regions 304 and 310 and being apart from the gate trenches.

Please refer to FIG. 3B for a preferred B1-B1′ cross-sectional view of FIG. 2A. The SiC power device has a similar structure to FIG. 3A, except that the present invention further comprises a grounded P (GP, as illustrated) region 329′ formed along a second portion of the second trench sidewall of the first type gate trench 303′ to ground the PS region 326′ to a source metal 312′ through the p2 body region 310′ and the source contact 323′ for the gate oxide electric field reduction.

Please refer to FIG. 3C for a preferred C1-C1′ cross-sectional view of FIG. 2A, which is a cross-sectional view of the gate electrode contact area of the SiC SBR. In the present invention, a second gate electrode (G2, as illustrated) 315″ is formed in an upper portion of each of the first type gate trenches 303″, and the second gate electrode 315″ is isolated from the N type epitaxial layer 302″ by a second gate oxide film (GOX2) 319″ along trench sidewalls and a second insulating film 316″ on a bottom of the gate trench, wherein the second gate oxide film 319″ has a thinner thickness than that of the second insulating film 316″, and furthermore, the second gate electrode 315″ is connected to a source metal 312″ through a trenched contact 333″.

Please refer to FIG. 3D for a preferred D1-D1′ cross-sectional view of FIG. 2A, which is a cross-sectional view of the gate electrode contact area of the SiC MOSFET. In the present invention, a first gate electrode (G1, as illustrated) 305′″ is formed in an upper portion of each of the first type gate trenches 303′″, and the first gate electrode 305′″ is isolated from the N type epitaxial layer 302′″ by a first gate oxide film (GOX1) 309′″ along a trench sidewall and a first insulating film 306′″ on a bottom of the gate trench, wherein the first gate oxide film 309′″ has a thinner thickness than the first insulating film 306′″, and furthermore, the first gate electrode 305′″ is connected to a gate metal runner 332′″ through a trenched contact 343′″.

Please refer to FIG. 3E for another preferred A1-A1′ cross-sectional view of FIG. 2A. The SiC power device has a similar structure to FIG. 3A, except that the present invention further comprises an N-shield (Ns, as illustrated) region 325″″ disposed below the PS region 326″″ in the N type epitaxial layer 302″″ with a doping concentration higher than that of the N type epitaxial layer 302″″ for the gate oxide protection.

Please refer to FIG. 3F for another preferred A1-A1′ cross-sectional view of FIG. 2A. The SiC power device has a similar structure to FIG. 3A, except that the present invention further comprises a deep P-shield (DPS, as illustrated) region 336″″′ disposed below the PS region 326″″′ in the N type epitaxial layer 302″″′.

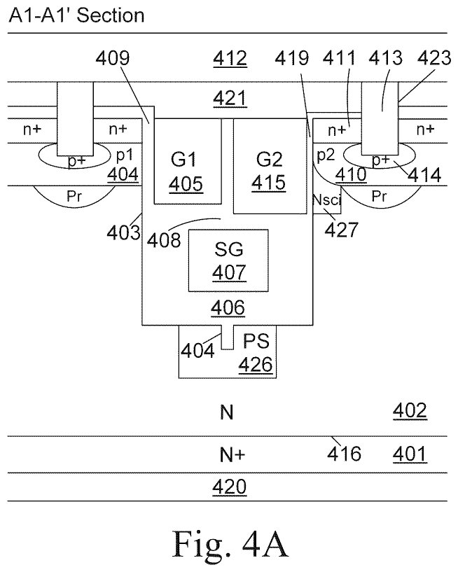

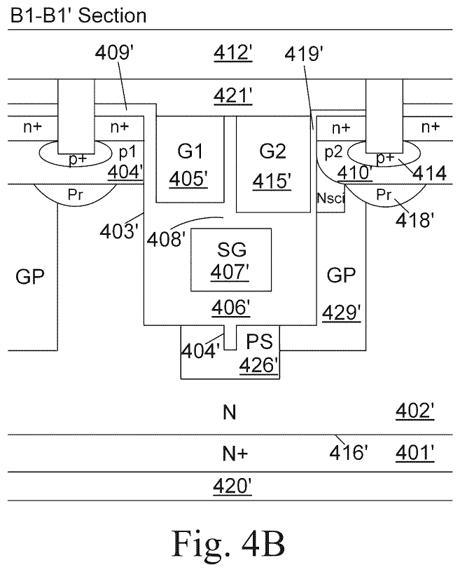

Please refer to FIG. 4A for another preferred A1-A1′ cross-sectional view of FIG. 2A. The SiC power device has a similar structure to FIG. 3A, except that in the present structure, inside each of the first type gate trenches 403, a shielded gate electrode (SG, as illustrated) 407 is disposed in a lower portion below the first and the second gate electrodes 405 and 415, and the shielded gate electrode 407 is isolated from the two gate electrodes by an inter-polysilicon oxide (IPO) film 408, and the thickness of the IPO film 408 below the first gate electrode 405 is thicker than that below the second gate electrode 415.

Please refer to FIG. 4B for another preferred B1-B1′ cross-sectional view of FIG. 2A. The SiC power device has a similar structure to FIG. 3B, except that in the present structure, inside each of the first type gate trenches 403′, a shielded gate electrode (SG, as illustrated) 407′ is disposed in a lower portion below the first and the second gate electrodes 405′ and 415′, and the shielded gate electrode 407′ is isolated from the two gate electrodes by an IPO film 408′, and the thickness of the IPO film 408′ below the first gate electrode 405′ is thicker than that below the second gate electrode 415′.

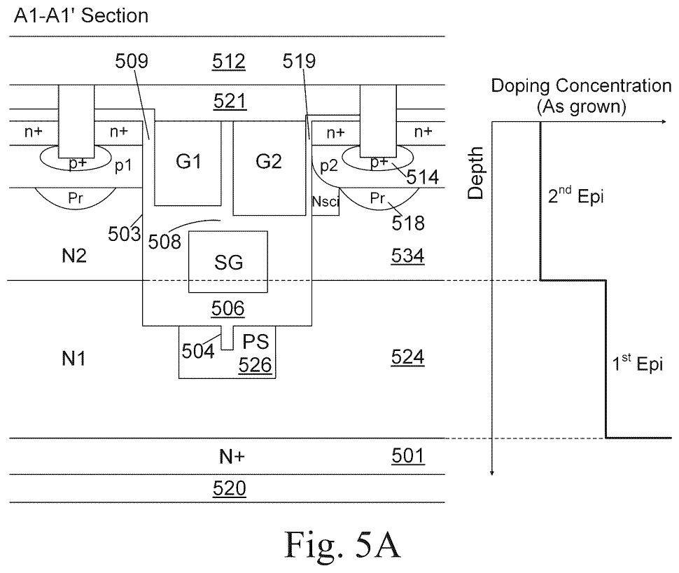

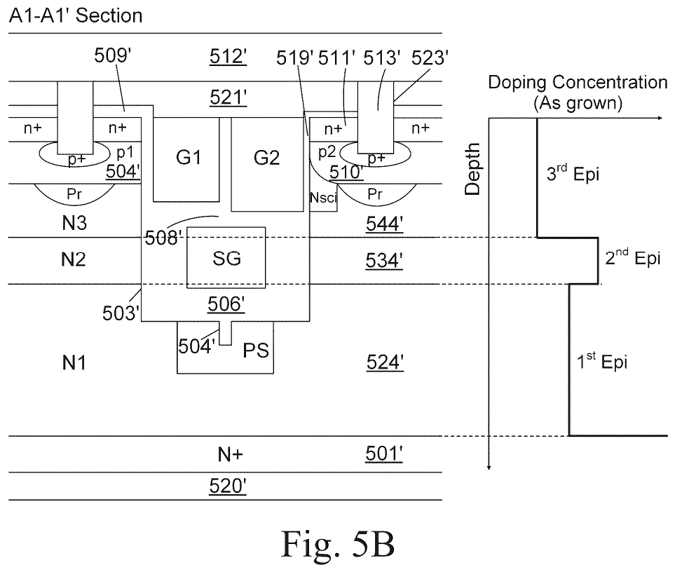

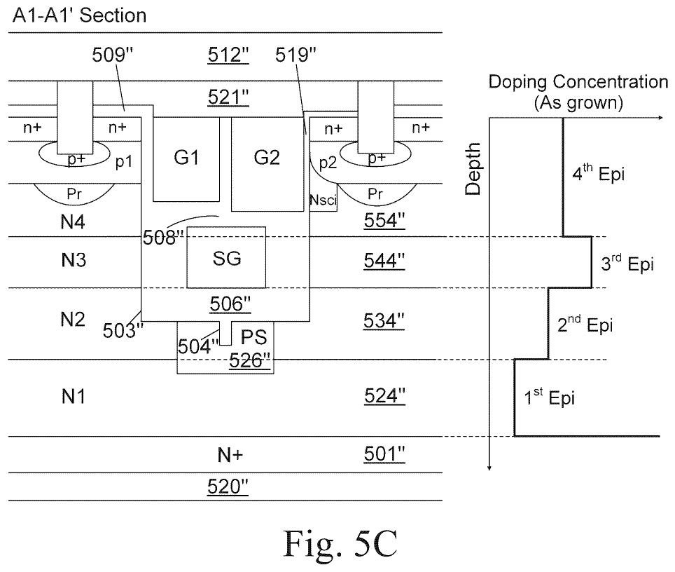

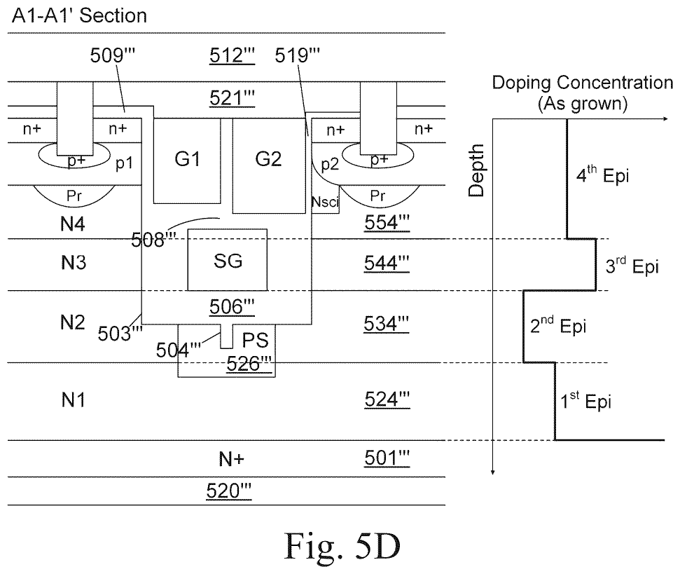

Please refer to FIG. 5A for another preferred A1-A1′ cross-sectional view of FIG. 2A, wherein the doping concentration variations of the N type epitaxial layer as grown are depicted along the vertical direction. The SiC power device has a similar structure to FIG. 4A, except for the different epitaxial layers. In this invention, the N type epitaxial layer comprises two stepped epitaxial layers of different doping concentrations including a bottom 1^{st} epitaxial layer (N1, as illustrated) 524 with a doping concentration D1 and a top 2^{nd} epitaxial layer (N2, as illustrated) 534 above the bottom 1^{st} epitaxial layer 524 with a doping concentration D2, wherein D2<D1, to increase the breakdown voltage and reduce the specific on-resistance.

Please refer to FIG. 5B for another preferred A1-A1′ cross-sectional view of FIG. 2A, wherein the doping concentration variations of the N type epitaxial layer as grown are depicted along the vertical direction. The SiC power device has a similar structure to FIG. 4A, except for the different epitaxial layers. In this invention, the N type epitaxial layer comprises three stepped epitaxial layers of different doping concentrations including a bottom 1^{st} epitaxial layer (N1, as illustrated) 524′ with a doping concentration D1, a middle 2^{nd} epitaxial layer (N2, as illustrated) 534′ above the bottom 1^{st} epitaxial layer 524′ with a doping concentration D2, and a top 3^{rd} epitaxial layer (N3, as illustrated) 544′ above the middle 2^{nd} epitaxial layer 534′ with a doping concentration D3, wherein D3<D1<D2, to increase the breakdown voltage and reduce the specific on-resistance.

Please refer to FIG. 5C for another preferred A1-A1′ cross-sectional view of FIG. 2A, wherein the doping concentration variations of the N type epitaxial layer as grown are depicted along the vertical direction. The SiC power device has a similar structure to FIG. 4A, except for the different epitaxial layers. In this invention, the N type epitaxial layer comprises four stepped epitaxial layers of different doping concentrations including a bottom 1^{st} epitaxial layer (N1, as illustrated) 524″ with a doping concentration D1, a 2^{nd} epitaxial layer (N2, as illustrated) 534″ on the 1^{st} epitaxial layer 524″ with a doping concentration D2, a 3^{rd} epitaxial layer (N3, as illustrated) 544″ on the 2^{nd} epitaxial layer 534″ with a doping concentration D3, and a 4^{th} epitaxial layer (N4, as illustrated) 554″ on the 3^{rd} epitaxial layer 544″ with a doping concentration D4, wherein said D1<said D2<said D4<said D3.

Please refer to FIG. 5D for another preferred A1-A1′ cross section of FIG. 2A, wherein the doping concentration variations of the N type epitaxial layer as grown are depicted along the vertical direction. The SiC power device has a similar structure to FIG. 5C, except that the relationship among the doping concentrations of the N type epitaxial layer in the present invention is said D2<said D1<said D4<said D3.

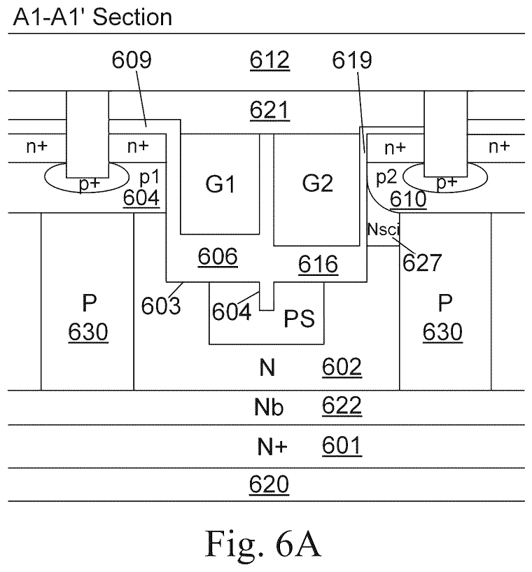

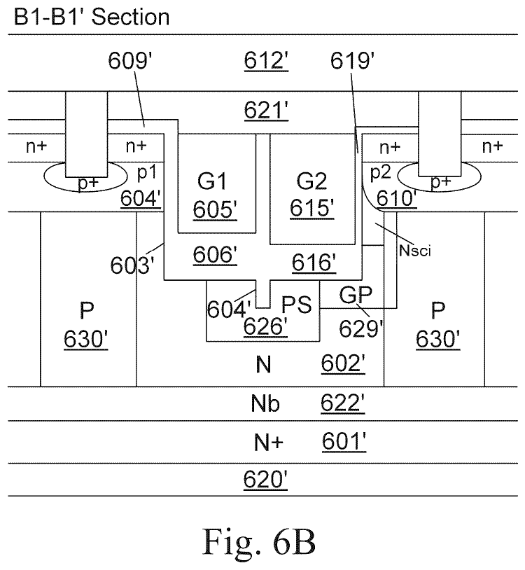

Please refer to FIG. 6A for another preferred A1-A1′ cross-sectional view of FIG. 2A, The SiC power device has a similar structure to FIG. 3A, except that the Pr regions 318 in FIG. 3A don't exist in FIG. 6A, and the present invention further comprises an N buffer layer (Nb, as illustrated) 622 with a resistivity Rb sandwiched between the N+ substrate 601 and the N type epitaxial layer 602, and the N type epitaxial layer 602 comprises a single epitaxial layer having a uniform doping concentration with a resistivity R, wherein R<Rb. Besides, P column regions 630 are introduced into the N epitaxial layer 602 to form a SJ region, comprising a plurality of alternating P regions 630 and N regions 602. The P column regions 630 are formed below the p1 and p2 body regions 604 and 610 and touch to the bottom surface of the N type epitaxial layer 602 by multiple epi method or by opening a deep trench filled up with an epitaxial layer of the second conductivity type method.

Please refer to FIG. 6B for another preferred B1-B1′ cross-sectional view of FIG. 2A, The SiC power device has a similar structure to FIG. 3B, except that the Pr regions 318′ in FIG. 3B don't exist in FIG. 6B, and the present invention further comprises an N buffer layer (Nb, as illustrated) 622′ with a resistivity Rb sandwiched between the N+ substrate 601′ and the N type epitaxial layer 602′, and the N type epitaxial layer 602′ comprises a single epitaxial layer having a uniform doping concentration with a resistivity R, wherein R<Rb. Besides, P column regions 630′ are introduced into the N epitaxial layer 602′ to form a SJ region, comprising a plurality of alternating P regions 630′ and N regions 602′. The P column regions 630′ are formed below the p1 and p2 body regions 604′ and 610′ and touch to the bottom surface of the N type epitaxial layer 602′ by multiple epi method or by opening a deep trench filled up with an epitaxial layer of the second conductivity type method.

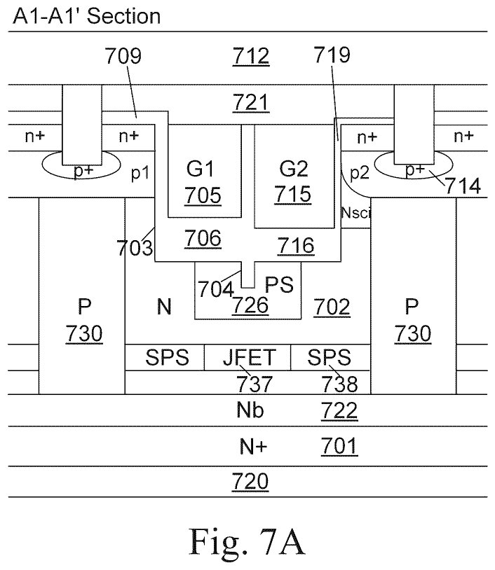

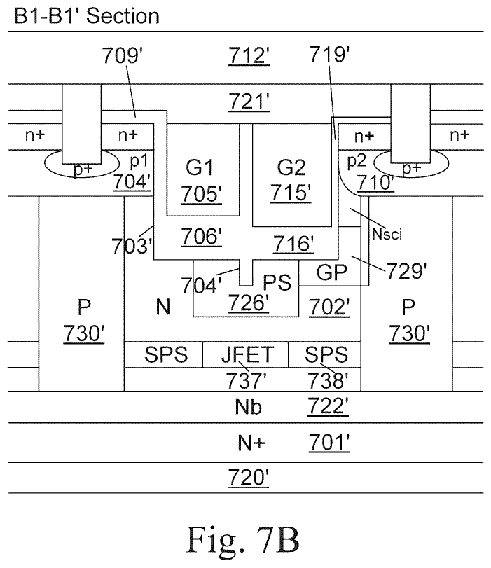

Please refer to FIG. 7A for another preferred A1-A1′ cross-sectional view of FIG. 2A, The SiC power device has a similar structure to FIG. 6A, except that the present invention further comprises two sidewall P-shield (SPS, as illustrated) regions 738 of the second conductivity type facing each other horizontally adjoining the P column (PC) regions 730 with a doping concentration higher than that of the PC regions 730, and a Junction Field Effect Transistor (JFET, as illustrated) region 737 of the first conductivity type is formed between the two SPS regions 738 with a doping concentration higher than that of the N type epitaxial layer 702.

Please refer to FIG. 7B for another preferred B1-B1′ cross-sectional view of FIG. 2A, The SiC power device has a similar structure to FIG. 6B, except that the present invention further comprises two sidewall P-shield (SPS, as illustrated) regions 738′ of the second conductivity type facing each other horizontally adjoining the P column (PC) region 730′ with a doping concentration higher than that of the PC regions 730′, and a Junction Field Effect Transistor (JFET, as illustrated) region 737′ of the first conductivity type is formed between the two SPS regions 738′ with a doping concentration higher than that of the N type epitaxial layer 702′.

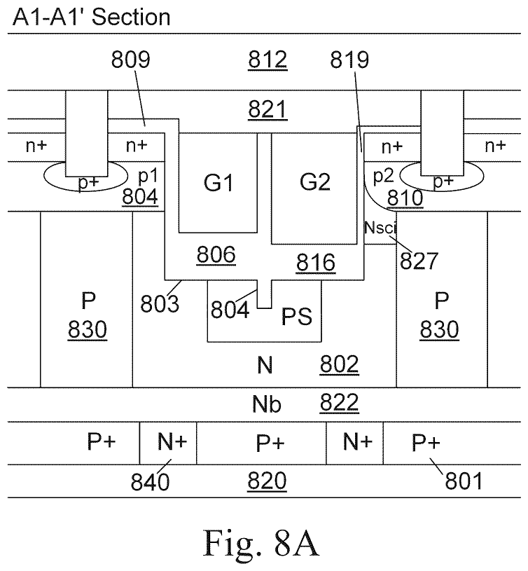

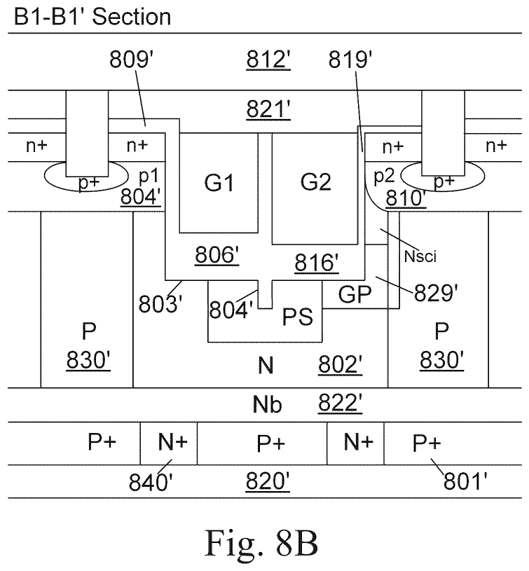

Please refer to FIG. 8A for another preferred A1-A1′ cross-sectional view of FIG. 2A, The SiC power device has a similar structure to FIG. 6A, except for the different substrate. In this invention, the SiC device is formed on a P+ substrate 801, and further comprises a plurality of heavily doped N+ regions 840 in the P+ substrate 801 to form a plurality of alternating P+ and N+ regions in the substrate. Moreover, the N buffer layer (Nb, as illustrated) 822 sandwiched between the P+ substrate 801 and the P column regions 830 in this invention has a resistivity Rb lower than a resistivity R of the N type epitaxial layer 802.

Please refer to FIG. 8B for another preferred B1-B1′ cross-sectional view of FIG. 2A, The SiC power device has a similar structure to FIG. 6B, except for the different substrate. In this invention, the SiC device is formed on a P+ substrate 801′, and further comprises a plurality of heavily doped N+ regions 840′ in the P+ substrate 801′ to form a plurality of alternating P+ and N+ regions in the substrate. Moreover, the N buffer layer (Nb, as illustrated) 822′ sandwiched between the P+ substrate 801′ and the P column regions 830′ in this invention has a resistivity Rb lower than a resistivity R of the N type epitaxial layer 802′.

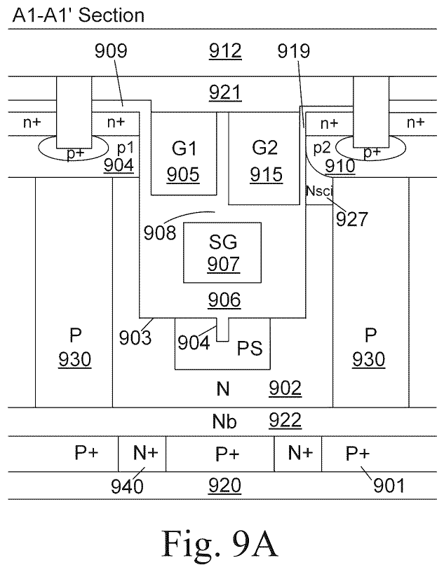

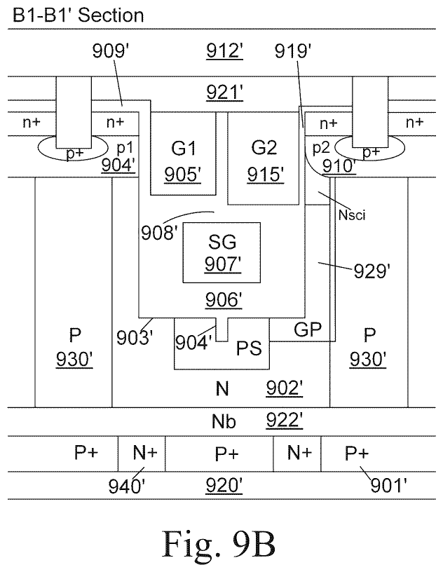

Please refer to FIG. 9A for another preferred A1-A1′ cross-sectional view of FIG. 2A. The SiC power device has a similar structure to FIG. 8A, except that in the present structure, inside each of the first type gate trenches 903, a shielded gate electrode (SG, as illustrated) 907 is disposed in a lower portion below the first and the second gate electrodes 905 and 915, and the shielded gate electrode 907 is isolated from the two gate electrodes by an IPO film 908, and the thickness of the IPO film 908 below the first gate electrode 905 is thicker than that below the second gate electrode 915.

Please refer to FIG. 9B for another preferred B1-B1′ cross-sectional view of FIG. 2A. The SiC power device has a similar structure to FIG. 8B, except that in the present structure, inside each of the first type gate trenches 903′, a shielded gate electrode (SG, as illustrated) 907′ is disposed in a lower portion below the first and the second gate electrodes 905′ and 915′, and the shielded gate electrode 907′ is isolated from the two gate electrodes by an IPO film 908′, and the thickness of the IPO film 908′ below the first gate electrode 905′ is thicker than that below the second gate electrode 915′.

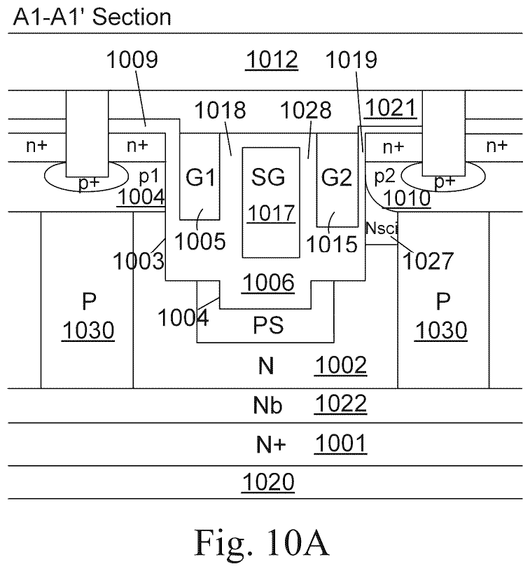

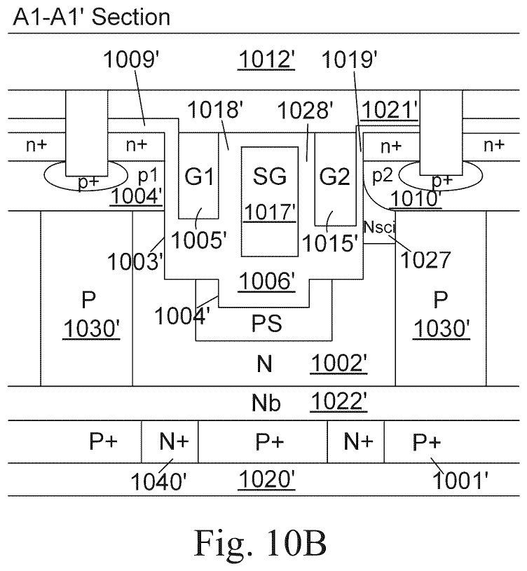

Please refer to FIG. 10A for another preferred A1-A1′ cross-sectional view of FIG. 2A. The SiC power device has a similar structure to FIG. 6A, except for the different gate trench structure. Inside each of the gate trenches 1003, a shielded gate electrode (SG, as illustrated) 1017 is disposed in the middle and a pair of split gate electrodes including a first gate electrode (G1, as illustrated) 1005 and a second gate electrode (G2, as illustrated) 1015 are disposed surrounding upper portions of the shielded electrode 1017. The shielded gate electrode 1017 is isolated from the first gate electrode 1005 and the second gate electrode 1015 by a third insulating film 1018 and a fourth insulating film 1028, respectively, wherein the third insulating films 1018 and the fourth insulating film 1028 are formed simultaneously during the growth of the gate oxides 1009 and 1019, respectively, in the manufacturing process. Moreover, the third insulating film 1018 has a thickness greater than that of the fourth insulating film 1028.

Please refer to FIG. 10B for another preferred A1-A1′ cross-sectional view of FIG. 2A. The SiC power device has a similar structure to FIG. 10A, except for the different substrate. In this invention, the SiC device is formed on a P+ substrate 1001′, and further comprises a plurality of heavily doped N+ regions 1040′ in the P+ substrate 1001′ to form a plurality of alternating P+ and N+ regions in the substrate. Moreover, the N buffer layer (Nb, as illustrated) 1022′ sandwiched between the P+ substrate 1001′ and the P column regions 1030′ in this invention has a resistivity Rb lower than a resistivity R of the N type epitaxial layer 1002′.

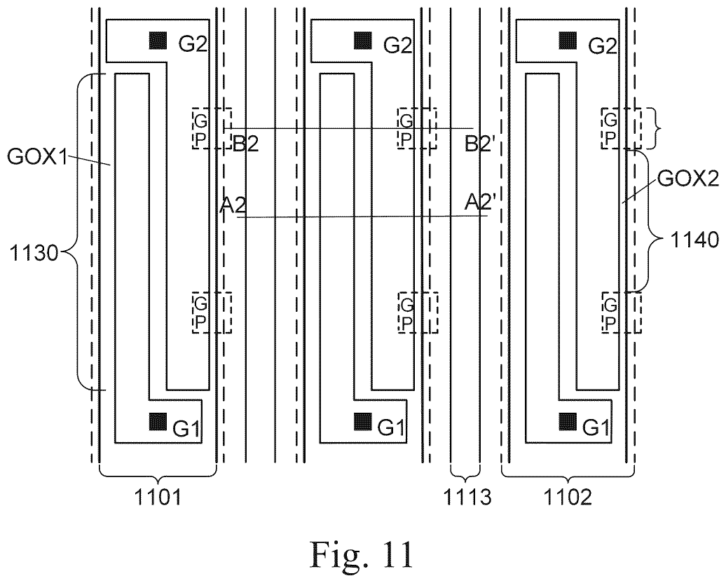

Please refer to FIG. 11 for another top view of a SiC power device having an asymmetric gate trench structure with stripe cells layout. The SiC power device has a similar structure to FIG. 2A, except that in the present invention, a P-shield (PS) region 1102 surrounds the stripe gate trench 1101 in each unit cell, and the PS region 1102 is grounded to a source metal through the grounded P (GP, as illustrated) regions and the trenched source contacts 1113.

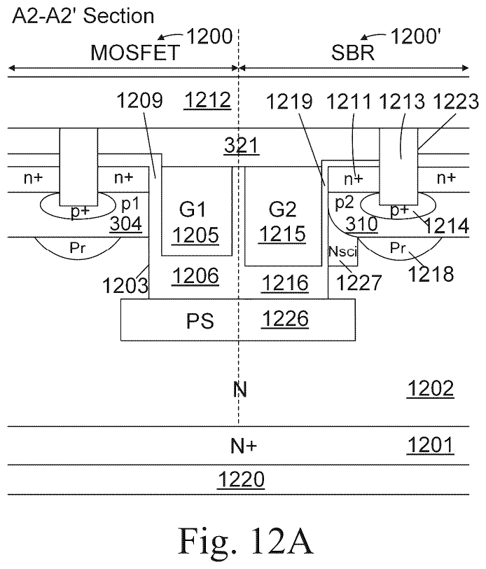

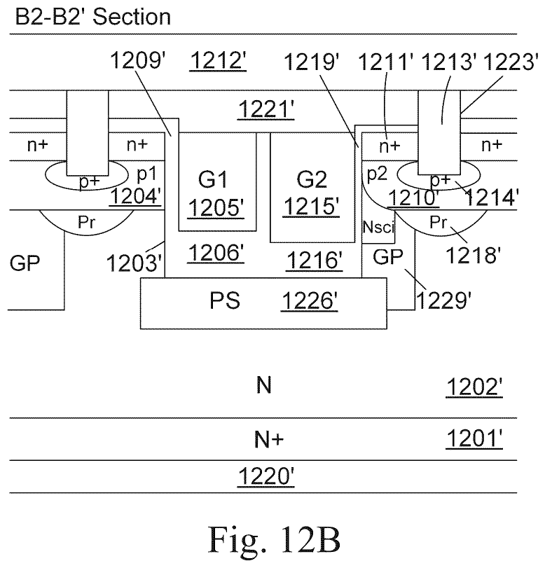

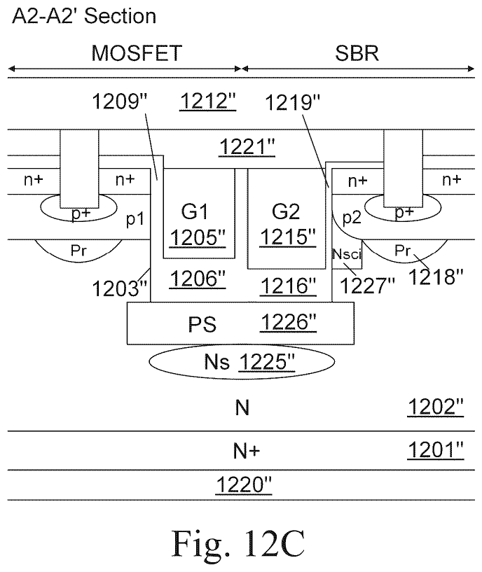

Please refer to FIG. 12A for a preferred A2-A2′ cross-sectional view of FIG. 11. The SiC power device has a similar structure to FIG. 3A, except that the present invention comprises one gate trench 1203, and a P-shield (PS, as illustrated) region 1226 surrounds a bottom of the gate trench 1203 with a width greater than that of the gate trench 1203.

Please refer to FIG. 12B for a preferred B2-B2′ cross-sectional view of FIG. 11. The SiC power device has a similar structure to FIG. 3B, except that the present invention comprises one gate trench 1203′, and a P-shield (PS, as illustrated) region 1226′ surrounds a bottom of the gate trench 1203′ with a width greater than that of the gate trench 1203′.

Please refer to FIG. 12C for another preferred A2-A2′ cross-sectional view of FIG. 11. The SiC power device has a similar structure to FIG. 12A, except that the present invention further comprises an N-shield (Ns, as illustrated) region 1225″ disposed below the PS region 1226″ in the N type epitaxial layer 1202″ with a doping concentration higher than that of the N type epitaxial layer 1202″ for the gate oxide protection.

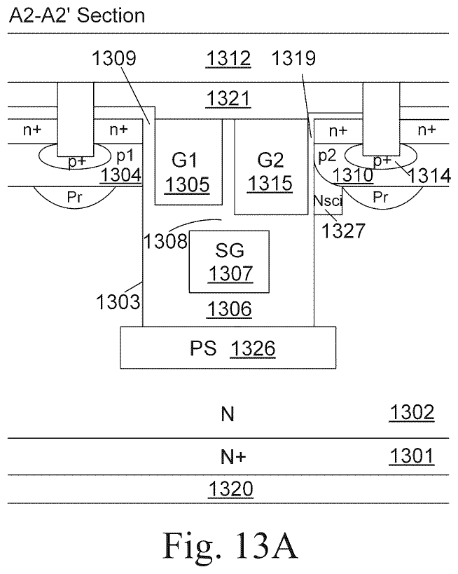

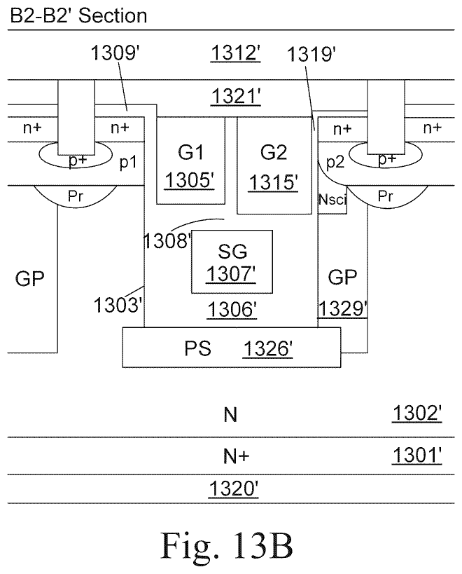

Please refer to FIG. 13A for another preferred A2-A2′ cross-sectional view of FIG. 11. The SiC power device has a similar structure to FIG. 4A, except that the present invention comprises one gate trench 1303, and a P-shield (PS, as illustrated) region 1326 surrounds a bottom of the gate trench 1303 with a width greater than that of the gate trench 1303.

Please refer to FIG. 13B for another preferred B2-B2′ cross-sectional view of FIG. 11. The SiC power device has a similar structure to FIG. 4B, except that the present invention comprises one gate trench 1303′, and a P-shield (PS, as illustrated) region 1326′ surrounds a bottom of the gate trench 1303′ with a width greater than that of the gate trench 1303′.

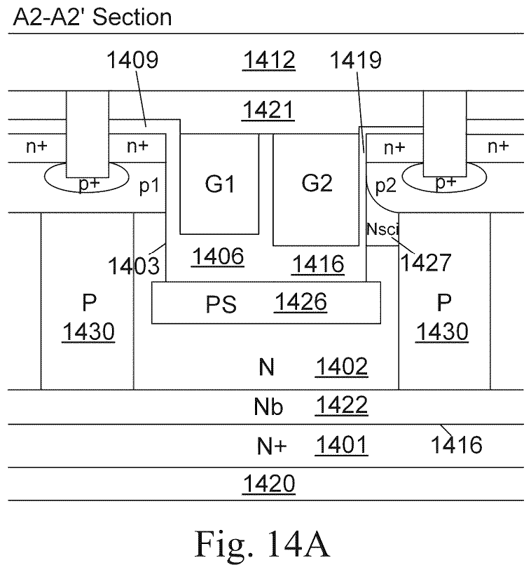

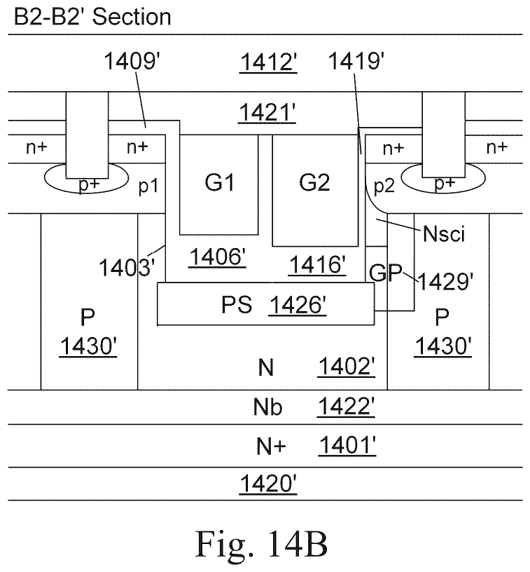

Please refer to FIG. 14A for another preferred A2-A2′ cross-sectional view of FIG. 11. The SiC power device has a similar structure to FIG. 6A, except that the present invention comprises one gate trench 1403, and a P-shield (PS, as illustrated) region 1426 surrounds a bottom of the gate trench 1403 with a width greater than that of the gate trench 1403.

Please refer to FIG. 14B for another preferred B2-B2′ cross-sectional view of FIG. 11. The SiC power device has a similar structure to FIG. 6B, except that the present invention comprises one gate trench 1403′, and a P-shield (PS, as illustrated) region 1426′ surrounds a bottom of the gate trench 1403′ with a width greater than that of the gate trench 1403′.

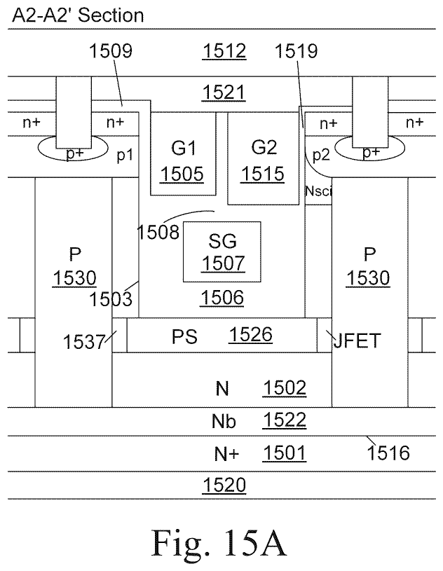

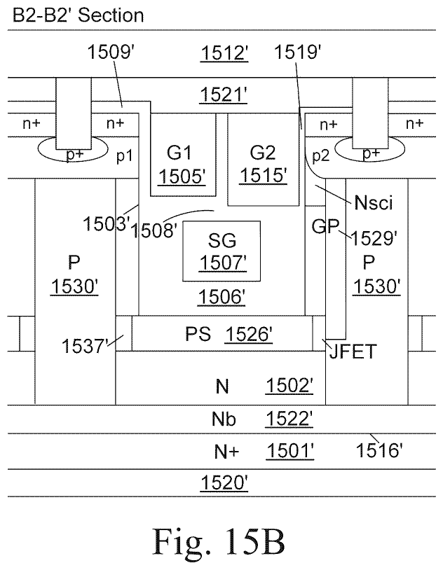

Please refer to FIG. 15A for another preferred A2-A2′ cross-sectional view of FIG. 11. The SiC power device has a similar structure to FIG. 14A, except that in the present structure, inside each of the gate trenches 1503, a shielded gate electrode (SG, as illustrated) 1507 is disposed in a lower portion below the first and the second gate electrodes 1505 and 1515, and the shielded gate electrode 1507 is isolated from the two gate electrodes by an IPO film 1508, and the thickness of the IPO film 1508 below the first gate electrode 1505 is thicker than that below the second gate electrode 1515. The present invention further comprises a Junction Field Effect Transistor (JFET, as illustrated) region 1537 of the first conductivity type formed between the PC region 1530 and the PS region 1526 with a doping concentration higher than that of the N type epitaxial layer 1502.

Please refer to FIG. 15B for another preferred B2-B2′ cross-sectional view of FIG. 11. The SiC power device has a similar structure to FIG. 14B, except that in the present structure, inside each of the gate trenches 1503′, a shielded gate electrode (SG, as illustrated) 1507′ is disposed in a lower portion below the first and the second gate electrodes 1505′ and 1515′, and the shielded gate electrode 1507′ is isolated from the two gate electrodes by an IPO film 1508′, and the thickness of the IPO film 1508′ below the first gate electrode 1505′ is thicker than that below the second gate electrode 1515′. The present invention further comprises a Junction Field Effect Transistor (JFET, as illustrated) region 1537′ of the first conductivity type formed between the PC region 1530′ and the PS region 1526′ with a doping concentration higher than that of the N type epitaxial layer 1502′.

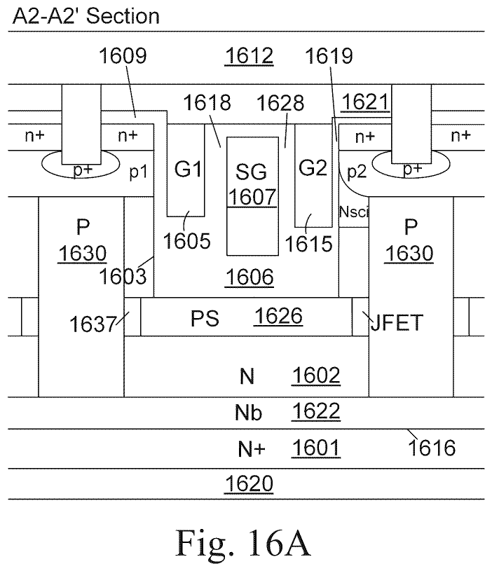

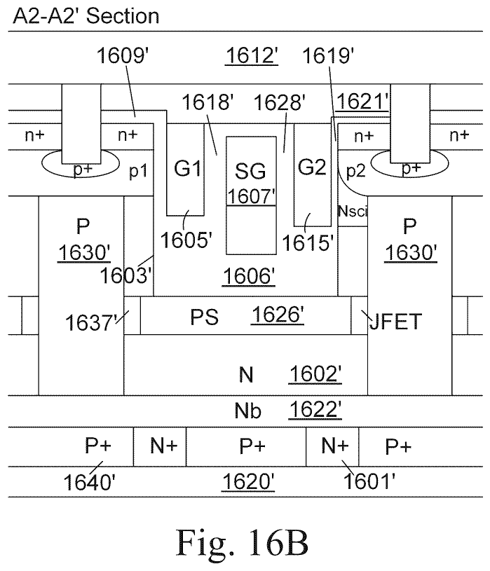

Please refer to FIG. 16A for another preferred A2-A2′ cross-sectional view of FIG. 11. The SiC power device has a similar structure to FIG. 15A, except for the different gate trench structure. Inside each of the gate trenches 1603, a shielded gate electrode (SG, as illustrated) 1607 is disposed in the middle and a pair of split gate electrodes including a first gate electrode (G1, as illustrated) 1605 and a second gate electrode (G1, as illustrated) 1615 are disposed surrounding upper portions of the shielded electrode 1607. The shielded gate electrode 1607 is isolated from the first gate electrode 1605 and the second gate electrode 1615 by a third insulating film 1618 and a fourth insulating film 1628, respectively, wherein the third insulating films 1618 and the fourth insulating film 1628 are formed simultaneously during the growth of the gate oxides 1609 and 1619, respectively, in the manufacturing process. Moreover, the third insulating film 1618 has a thickness greater than that of the fourth insulating film 1628.

Please refer to FIG. 16B for another preferred A2-A2′ cross-sectional view of FIG. 11. The SiC power device has a similar structure to FIG. 16A, except for the different substrate. In this invention, the SiC device is formed on a P+ substrate 1601′, and further comprises a plurality of heavily doped N+ regions 1640′ in the P+ substrate 1601′ to form a plurality of alternating P+ and N+ regions in the substrate. Moreover, the N buffer layer (Nb, as illustrated) 1622′ sandwiched between the P+ substrate 1601′ and the P column region 1630′ in this invention has a resistivity Rb lower than a resistivity R of the N type epitaxial layer 1602′.

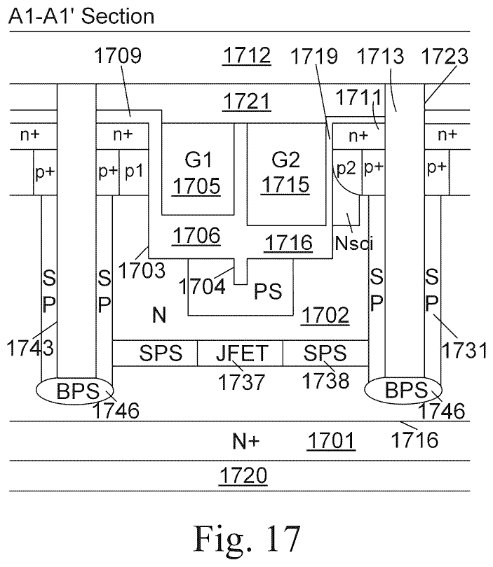

Please refer to FIG. 17 for another preferred A1-A1′ cross-sectional view of FIG. 2A. The SiC power device has a similar structure to FIG. 7A, except that the P column regions 730 and the N buffer (Nb, as illustrated) region 722 in FIG. 7A don't exist in FIG. 17, and the present invention further comprises a source-body contact (SBC) trench 1743 penetrating through the n+ source region 1711 and the p body regions and extending into the N type epitaxial layer 1702, a bottom P-shield region (BPS, as illustrated) 1746 surrounding a bottom of the SBC trench 1743 and being spaced apart from the gate trenches 1703 and 1704, a sidewall P (SP, as illustrated) region 1731 formed along sidewalls of the SBC trench 1743 connecting the BPS region 1746 to the body contact region, at least two SPS regions 1738 facing each other horizontally adjoining the SP region 1731, and an N type JFET region 1737 formed between the two SPS regions 1738 with a doping concentration higher than that of the N type epitaxial layer 1702.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. An integrated circuit comprising a SiC MOSFET and a SiC super barrier rectifier (SBR) disposed in each unit cell having an asymmetric stripe gate trench structure comprising:
an epitaxial layer of a first conductivity type grown on a substrate;
at least one stripe gate trench surrounded by a source region of a first conductivity type having a first gate trench sidewall for the SiC MOSFET and a first portion of a second gate trench sidewall for the SiC SBR, said first gate trench sidewall is opposite to said second gate trench sidewall;
a first gate electrode of said SiC MOSFET and a second gate electrode of said SiC SBR disposed in said stripe gate trench side by side;
said first gate electrode isolated from said epitaxial layer with a first gate oxide of said SiC MOSFET on said first gate trench sidewall, and said second gate electrode isolated from said epitaxial layer with a second gate oxide of said SiC SBR on said second gate trench sidewall, wherein said second gate oxide has a thickness less than a thickness of said first gate oxide;
said first gate electrode surrounded with a first insulating film on a bottom of said stripe gate trench and said first insulating film having a thickness greater than that of said first gate oxide; said second gate electrode surrounded with a second insulating film on a bottom of said stripe gate trench and said second insulating film having a thickness greater than that of said second gate oxide; and said first insulating film having a thickness greater than that of said second insulating film;
said source region encompassed in a first body region of said second conductivity type at one side of a top portion of said epitaxial layer in said SiC MOSFET and encompassed in a second body region of said second conductivity at the other side in said SiC SBR;
a first channel region formed between said first body region and said source region along said first gate trench sidewall;
a short channel implant region of said first conductivity type formed along an upper portion of said second gate trench sidewall and surrounding said second gate electrode;
a second channel region formed between said second body region and said source region along said second gate trench sidewall; wherein said second channel region has a shorter channel length than that of said first channel region;
said second gate electrode shorted to a source metal through a gate contact of said SiC SBR;
a first P-shield (PS) region of said second conductivity type formed below said stripe gate trench;
at least one grounded P (GP) region of said second conductivity type surrounding a second portion of said second trench sidewall, connecting with said second body region and said first PS region; and
said first and second body regions and said source region being shorted to said source metal through source contacts.

2. The integrated circuit of claim 1, wherein said stripe gate trench has a first type gate trench and a second type gate trench; said first type gate trench is above said second type gate trench and has a trench width wider than that of said second type gate trench;
said first gate electrode disposed in said first type gate trench surrounded with said first insulating film on a bottom of said first type gate trench, and with said first gate oxide on first gate trench sidewall of said first type gate trench; said second gate electrode disposed in said first gate trench surrounded with said second insulating film on a bottom of said first type stripe gate trench, and with said second gate oxide on said second gate trench sidewall of said first type gate trench; and
said first PS region of said second conductivity type surrounding a bottom and sidewalls of said second type stripe gate trench filled up with said first insulating film.

3. The integrated circuit of claim 1, further comprising a second P-shield region of said second conductivity type for the gate oxide electric-filed reduction, adjoining a lower surface of said body region and being apart from said stripe gate trench.

4. The integrated circuit of claim 2, further comprising a third P-shield region of said second conductivity type below said first PS region.

5. The integrated circuit of claim 1, further comprising a N-shield region of said first conductivity type below said first PS region having a doping concentration higher than that of said epitaxial layer.

6. The integrated circuit of claim 1, further comprising a super junction (SJ) structure comprising a P column (PC) region of said second conductivity type disposed on a buffer layer of said first conductivity type with a resistivity Rb sandwiched between said substrate and said epitaxial layer, and said PC region is connected to said body region.

7. The integrated circuit of claim 6, wherein said substrate has said first conductivity type and said epitaxial layer comprises a single epitaxial layer having a uniform doping concentration with a resistivity R, said R<said Rb.

8. The integrated circuit of claim 6, wherein said substrate has said second conductivity type and said epitaxial layer comprises a single epitaxial layer having a uniform doping concentration with a resistivity R, said R>said Rb.

9. The integrated circuit of claim 6, wherein said substrate has said second conductivity type, further comprising a plurality of heavily doped regions of said first conductivity type in said substrate to form a plurality of alternating P+ and N+ regions in said substrate.

10. The integrated circuit of claim 6, further comprising at least two sidewall P-shield (SPS) regions of said second conductivity type facing each other with a doping concentration higher than a doping concentration of said PC region, adjoining said PC region and being spaced apart from said body region, and a Junction Field Effect Transistor (JFET) region of said first conductivity type formed between said two SPS regions with a doping concentration higher than that of said epitaxial layer.

11. The integrated circuit of claim 6, further comprising a JFET region of said first conductivity type formed between said PC and said PS regions with a doping concentration higher than that of said epitaxial layer.

12. The integrated circuit of claim 1, further comprising a shielded gate electrode disposed in a lower portion of said first type stripe gate trench below said first and said second gate electrodes; said shielded gate electrode insulated from said epitaxial layer by a third insulating film with a thickness below said first gate electrode thicker than a thickness below said second gate electrode.

13. The integrated circuit of claim 1, further comprising a shielded gate electrode disposed in a middle of said first type stripe gate trench, and said first and said second gate electrodes are a pair of split gate electrodes disposed surrounding an upper portion of said shielded gate electrode.

14. The integrated circuit of claim 12, wherein said epitaxial layer is a single epitaxial layer with a uniform doping concentration.

15. The integrated circuit of claim 12, wherein said epitaxial layer comprises at least two stepped epitaxial layers of different doping concentrations including a bottom epitaxial layer with a doping concentration D1 and a top epitaxial layer above said bottom epitaxial layer with a doping concentration D2, wherein said D2<said D1.

16. The integrated circuit of claim 12, wherein said epitaxial layer comprises at least three stepped epitaxial layers of different doping concentrations including a bottom epitaxial layer with a doping concentration D1, a middle epitaxial layer with a doping concentration D2 and a top epitaxial layer with a doping concentration D3, wherein said D3<said D1<said D2.

17. The integrated circuit of claim 12, wherein said epitaxial layer comprises at least four stepped epitaxial layers of different doping concentrations including a first epitaxial layer on said substrate with a doping concentration D1, a second epitaxial layer on said first epitaxial layer with a doping concentration D2, a third epitaxial layer on said second epitaxial layer with a doping concentration D3, and a fourth epitaxial layer on said third epitaxial layer with a doping concentration D4, wherein said D1<said D2<said D4<said D3 or said D2<said D1<said D4<said D3.

18. The integrated circuit of claim 1, wherein said GP region is disposed at each end of said second gate electrode and said SBR region disposed between two GP regions.

19. The integrated circuit of claim 1, wherein said GP and SBR regions are formed alternately along said second gate trench sidewall of said stripe gate trench.

20. The integrated circuit of claim 1, further comprising a source-body contact (SBC) trench penetrating through said source region and said body region and extending into said epitaxial layer, a bottom P-shield (BPS) region of said second conductivity type surrounding a bottom of said SBC trench and being spaced apart from said stripe gate trench, a sidewall P (SP) region of said second conductivity type formed along sidewalls of said SBC trench connecting said bottom P-shield region to said body contact region, at least two SPS regions of said second conductivity type facing each other horizontally adjoining said SP region, and a JFET region of said first conductivity type formed between said two SPS regions with a doping concentration higher than that of said epitaxial layer.
